(19) United States
(12) Patent Application Publication
(10) Pub. No.: US 2014/0264855 A1
(43) Pub. Date: Sep. 18, 2014

(54) SEMICONDUCTOR COMPOSITE LAYER STRUCTURE AND SEMICONDUCTOR PACKAGING STRUCTURE HAVING THE SAME THEREOF

(71) Applicant: MACRONIX INTERNATIONAL CO., LTD., (US)

(72) Inventors: Ming-Tung Lee, Taoyuan County (TW); Shih-Chin Lien, New Taipei City (TW); Shiaw-Chang Lin, Miaoli County (TW); Chin-Yei Tseng, Keelung City (TW); Kwo-Hau Wu, Hsin-Chu City (TW); Shyi-Yuan Wu, Hsinchu City (TW)

(73) Assignee: MACRONIX INTERNATIONAL CO., LTD., Hsinchu (TW)

(21) Appl. No.: 13/851,985

(22) Filed: Mar. 28, 2013

Related U.S. Application Data
(60) Provisional application No. 61/778,502, filed on Mar. 13, 2013.

(51) Int. Cl. H01L 23/532; H01L 23/498

(52) U.S. Cl. CPC H01L 23/53257; H01L 23/49816
USPC 257/738

(57) ABSTRACT

A semiconductor composite layer structure disposed on a substrate having an electronic circuit structure and a first conductive layer is disclosed. The semiconductor composite layer structure comprises a plurality of dielectric layers, a first wetting layer, a stiff layer and a second wetting layer. The dielectric layers are disposed on the substrate separately. The first wetting layer is disposed on the dielectric layer and the substrate between the dielectric layers. The stiff layer is disposed on the first wetting layer. The second wetting layer is disposed on stiff layer, for contacting with a second conductive layer.

This application claims the benefit of U.S. provisional application Ser. No. 61/778,502, filed Mar. 13, 2013, the subject matter of which is incorporated herein by reference.

### BACKGROUND OF THE INVENTION

1. Field of the Invention

The invention is related to a semiconductor packaging structure, and more particularly to a semiconductor packaging structure having a specific semiconductor composite layer structure.

2. Description of the Related Art

During a semiconductor packaging process, a conductive interconnect in an integrated circuit devices is usually formed by a forming a wetting layer to contact with a conductor layer for the interface between the conductive interconnect an conductor layer. Since the wetting layer is a soft material and can react with and attach to the conductor layer well, the utilization of the wetting layer can reduce the problems of de-lamination.

However, when the conductive interconnect is used as a bond pad, the soft wetting layer may cause the problems of pad cracking. Besides, the wetting layer can react with the conductor layer easily, thereby making the stress under the bond pad between the dielectric layer and the conductor layer mismatching and causing the pad peeling. Therefore, the process is unstable and the product making by the process is unreliable.

### SUMMARY OF THE INVENTION

This invention is related to a semiconductor packaging structure. By using a specific semiconductor composite layer structure, problems of de-lamination and wire bonding ball peeling can be reduced in this semiconductor packaging structure.

According to a first aspect of the present invention, a semiconductor composite layer structure disposed on a substrate having an electronic circuit structure and a first conductive layer is disclosed. The semiconductor composite layer structure comprises a plurality of dielectric layers, a first wetting layer, a stiff layer and a second wetting layer. The dielectric layers are disposed on the substrate separately. The first wetting layer is disposed on The dielectric layer and the substrate between the dielectric layers. The stiff layer is disposed on the first wetting layer. The second wetting layer is disposed on stiff layer, for contacting with a second conductive layer.

According to a first aspect of the present invention, a semiconductor packaging structure, comprising a substrate, a semiconductor composite layer structure, a passivation layer and a wire bonding ball is disclosed. The substrate comprises an electronic circuit structure and a first conductive layer disposed on the electronic circuit structure. The semiconductor composite layer structure is disposed on the first conductive layer and corresponding to a first region of the substrate. The semiconductor composite layer structure comprises a plurality of dielectric layers, a first wetting layer, a stiff layer and a second wetting layer. The dielectric layers are disposed on the substrate separately. The first wetting layer is disposed on the dielectric layers and the substrate between the dielectric layers. The stiff layer is disposed on the first wetting layer. The second wetting layer is disposed on the stiff layer. The second conductive layer is disposed on the second wetting layer. The passivation layer is disposed on the second conductive layer, and the passivation layer having an opening. The wire bonding ball is disposed in the opening and corresponding to a second region of the substrate. A distance is between the first region and the second region.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a cross section diagram of a semiconductor packaging structure according to an embodiment of the invention.

FIGS. 2˜7 illustrate process flow diagrams of a semiconductor packaging structure in FIG. 1.

FIG. 8 illustrates a cross section diagram of a semiconductor packaging structure according to another embodiment of the invention.

FIG. 9 illustrates a top view diagram of a semiconductor packaging structure according another embodiment of the invention.

FIGS. 10A and 10B respectively illustrate a top view diagram and a cross section diagram of a semiconductor packaging structure according to still another embodiment of the invention.

FIGS. 11A and 11B respectively illustrate a top view diagram and a cross section diagram of a semiconductor packaging structure according to still another embodiment of the invention.

### DETAILED DESCRIPTION OF THE INVENTION

### First Embodiment

Referring to FIG. 1, which illustrates a cross section diagram of a semiconductor packaging structure according to an embodiment of the invention. As shown in FIG. 1, the semiconductor packaging structure 10 comprises a substrate 110 having a base substrate 100 and a first conductive layer 120, a semiconductor composite layer structure 140, a second conductive layer 160, a passivation layer 180 and a wire bonding ball 190. The base substrate 100 comprises an electronic circuit structure (not illustrated). The first conductive layer 120 is disposed on the electronic circuit structure. The base substrate 100 can comprise a silicon base substrate or a non-silicon base substrate, and the invention is not limited thereto.

The semiconductor composite layer structure 140 is disposed on a substrate 110 having an electronic circuit structure (not illustrated) and a first conductive layer 120, the semiconductor composite layer structure 140 can be a metal dielectric layer (inter-metal dielectric, IMD), and can comprise a plurality of dielectric layers 142, a first wetting layer 144, a stiff layer 146 and a second wetting layer 148. The first conductive layer can comprise silicon oxide. In one embodiment, the base substrate 100 can be a structure of circuit under pad (CUP).

In FIG. 1, the dielectric layer 142 is disposed on the substrate 110 separately, and each dielectric layer 142 can be polygon. However, the invention is not limited thereto. The dielectric layers 142 can also be rectangle, trapezoid or T shaped. Each dielectric layer 142 can comprises a top surface S1 and at least one side surface S2. The first wetting layer 144 covers the top surface S1 and the side surface S2 of each dielectric layer 142, and the surface S3 of the substrate 110 exposed between the dielectric layers 142.

In one embodiment, the stiff layer 144 can be metal or inter-metallic compound. For example, the stiff layer 144 can be tantalum (Ta) or titanium nitride (TiN). The stiff layer 144 can be formed by a reactive DC sputtering process, and the stiff layer 144 is used for providing a resistance against the stress of wire bonding.

In one embodiment, by controlling the parameters of the process, a stiff layer 144 with an uniform thickness can be formed. For example, an edge region E is at a connecting area of the top surface S1 and the at least one side surface S2 of the stiff layer 144. The thickness d1 of the stiff layer 144 on the first wetting layer 144 and corresponding to the top surface S1, and the thickness d4 of the stiff layer 144 on the first wetting layer 144 and corresponding to the edge region E is larger than the thickness d2 of the stiff layer 144 on the first wetting layer corresponding to the at least one side surface S2. Besides, the thickness d1 and the thickness d4 of the stiff layer 144 are larger than the thickness d3 of the stiff layer 144 on the surface S3 of the substrate 110. In other words, a stiff layer 144 having thickness d1>thickness d3>thickness d2, and having thickness d4>thickness d3>thickness d2 can be designed. Since the stiff layer 144 corresponding to the edge region E and the top surface S1 is thicker, a better support can be provided during wire bonding process. The thickness of the stiff layer 144 is not limited thereto and can be adjusted based on the process requirement.

The first wetting layer 144 is disposed on the surface S3 of the substrate 110 between the dielectric layers 142. The stiff layer 146 is disposed on the first wetting layer 144. The second wetting layer 148 is disposed on the stiff layer 146, for contacting with a second conductive layer 160. The second conductive layer can comprise aluminum (Al). The first wetting layer 144 and the stiff layer 146 can be used to solve the problems of stress mismatching between the first conductive layer 120 and the dielectric layers 142, and reduce de-lamination during pad bonding. The configuration of the second wetting layer 148 can improve the adhesive strength between the semiconductor composite layer structure 140 and the second conductive layer 160, and avoid voids at the interface between the semiconductor composite layer structure 140 and the second conductive layer 160.

In one embodiment, the first wetting layer 144 and the second wetting layer 148 can be metal or alloy. For example, the first wetting layer 144 and the second wetting layer 148 can be titanium (Ti) or titanium tungsten (TiW), and the invention is not limited thereto. The first wetting layer 144 and the second wetting layer 148 can comprise the same metal (or alloy) or different metals (or alloys).

The second conductive layer 160 is disposed on the second wetting layer 148. The passivation layer 180 is disposed on the second conductive layer 160, and the passivation layer 180 has an opening O. The wire bonding ball 190 can be disposed in opening O, and the wire bonding ball can comprise copper (Cu).

In one experiment, if merely one wetting layer is disposed on the dielectric layer 142 (without composite layer), the probability of de-lamination ratio is about 1.2% and the probability of peeling of wire bonding ball 190 is about 1%. If the first wetting layer 144, the stiff layer 146 and second wetting layer 148 are disposed on the dielectric layer 142 (as a semiconductor composite layer structure 140), the probability of de-lamination ratio is reduced to about 0.6% and the probability of peeling of wire bonding ball 190 is reduced to less than 0.6%.

The manufacturing process of the semiconductor packaging structure 10 is described below. Referring to FIGS. 2˜7, a substrate 110 comprising an electronic circuit structure (not illustrated) and a base substrate 100, and first conductive layer 120 is provided. A dielectric layer 141 is formed on the first conductive layer 120.

Referring to FIGS. 3˜4, an etching process is performed to form a plurality of via holes V and a plurality of dielectric layer 142. Then, a first wetting layer 144 is formed on the dielectric layers 142 and a surface of the substrate 110 between the dielectric layers 142.

Referring to FIGS. 5˜6, a stiff layer 146 can be formed on the first wetting layer 144 by a reactive DC sputtering. Then, a second wetting layer 148 can be formed on the stiff layer 146. In this case, the semiconductor composite layer structure 140 comprising dielectric layer 142, a first wetting layer 144, a stiff layer 146 and a second wetting layer 148 is formed.

Referring to FIG. 7, a second conductive layer 160 is formed on the second wetting layer 148 and fills the notch caused by the via holes V (illustrated in FIG. 3). Then, a planarization process can be performed. Then, a passivation layer 180 is formed and patterned, such that the passivation layer 180 having an opening O. A wire bonding ball 190 is disposed in the opening O. At this time, a semiconductor packaging structure 10 is formed.

Referring to FIG. 8, which illustrates a cross section diagram of a semiconductor packaging structure according to another embodiment of the invention. As shown in FIG. 8, the semiconductor packaging structure 20 comprises a substrate 200, a first conductive layer 220, a semiconductor composite layer structure 240, a second conductive layer 260, a passivation layer 280 and a wire bonding ball 290. The substrate 200 comprises a base substrate 202 having an electronic circuit structure (not illustrated) and a third conductive layer 204, the third conductive layer can be a metal wire and is used as a routing wire of the electronic circuit structure.

The materials and manufacturing process of the first conductive layer 220, the semiconductor composite layer structure 240, the second conductive layer 260, the passivation layer 280 and the wire bonding ball 290 of the semiconductor packaging structure 20 can be the same or similar to that of the first conductive layer 120, the semiconductor composite layer structure 140, the second conductive layer 160, the passivation layer 180 and the wire bonding ball 190 of the semiconductor packaging structure 10. The similarities are not repeated herein.

As shown in FIG. 8, the semiconductor composite layer structure 240 is disposed on the first conductive layer 220 and corresponds to a first region A of the substrate 200. The wire bonding ball 290 is disposed in the opening O′ of the passivation layer 280 and corresponds to a second region B of the substrate 200. The first region A has a length R1, the second region B has a length R2. A distance R3 is between the first region A and the second region B.

In one embodiment, the length R1 of the first region A can be larger than or equal to 10 μm, the length R2 of the second region B can be larger than or equal to 60 μm. The distance R3 between the first region and the second region can be larger than or equal to 10 μm. The thickness R4 of the second conductive layer 260 upon the semiconductor composite layer structure 240 can be larger than or equal to 1 μm. The wire bonding ball 290 comprises a wire 290a. The wire 290a has a diameter smaller than or equal to 30 μm.

FIG. 9 illustrates a top view diagram of a semiconductor packaging structure 20′ according another embodiment of the invention. Referring to FIG. 9, in this embodiment, the semiconductor composite layer structure (not illustrated) is disposed on the first region A1 of the substrate 200′. The wire bonding ball (not illustrated) is disposed in an opening of a passivation layer (not illustrated) and corresponds to a second region B1 of the substrate 200′. The first region A1 surrounds the second region B1. The first region A1 has a length R11, the second region B1 has a length R12. A gap region C1 is between the first region A1 and the second region B1 and has a distance R13. The length R12 and the composition of the semiconductor composite layer structure may affect the quantity of pad crack, and the experiment result is shown in Table 1.

TABLE 1

| | R12 length | Number of |
|---|---|---|
| | (μm) | pad cracks |
| merely one wetting layer on | 45 | 19 |
| the dielectric layer | 50 | 9 |
| | 60 | 8 |
| a wetting layer and a stiff | 45 | 17 |
| layer on the dielectric layer | 50 | 2 |
| | 60 | 1 |
| a first wetting layer, a stiff | 45 | 7 |
| layer and second wetting | 50 | 1 |
| layer on the dielectric layer | 60 | 0 |

Please referring to FIG. 9 and Table 1. In Table 1, the semiconductor composite layer structure of merely one wetting layer on the dielectric layer, the semiconductor composite layer structure of a wetting layer and a stiff layer on the dielectric layer, and the semiconductor composite layer structure of a first wetting layer, a stiff layer and second wetting layer on the dielectric layer with different R12 length are compared in Table 1. As shown in Table 1, the structure of a first wetting layer, a stiff layer and a second wetting layer on the dielectric layer with R12 being equal to 60 μm achieves no pad crack. Besides, the composite structure of the first wetting layer, the stiff layer and the second wetting layer on the dielectric layer has less pad crack probability.

FIGS. 10A and 10B illustrate a top view diagram and a cross section diagram of a semiconductor packaging structure according to still another embodiment of the invention. In order to simplify the description, merely the first conductive layer 220, the semiconductor composite layer structure 240a and the second conductive layer 260 are illustrated.

Please referring to FIGS. 10A and 10B. The semiconductor composite layer structure 240a is disposed on a first region A2 and a second region B2 of the substrate (not illustrated). The wire bonding ball (not illustrated) is disposed in an opening of a passivation layer (not illustrated), and corresponds to a second region B2 of the substrate. The first region A2 surrounds the second region B2. The first region A2 has a length R21, the second region B2 has a length R22. A gap region C2 is between the first region A2 and the second region B2, and has a distance R23. The difference between the semiconductor packaging structure 25 in FIG. 10A and the semiconductor packaging structure 20 in FIG. 9 is that the semiconductor composite layer structure 240a of the semiconductor packaging structure 25 is also disposed at the second region B2. In this embodiment, the sum of the length R22 and the distance R23 (R22+R23), and the composition of the semiconductor composite layer structure may affect the quantity of pad cracking and the experiment result is illustrated in Table 2.

TABLE 2

| | Sum of length R22 | |
|---|---|---|
| | and distance R23 | Number of |
| | (R22 + R23) (μm) | pad cracks |
| merely one wetting layer on | 45 | 16 |
| the dielectric layer | 50 | 12 |
| | 60 | 8 |
| a wetting layer and a stiff | 45 | 12 |
| layer on the dielectric layer | 50 | 4 |
| | 60 | 10 |
| a first wetting layer, a stiff | 45 | 0 |
| layer and second wetting | 50 | 0 |
| layer on the dielectric layer | 60 | 1 |

Please refer to FIGS. 10A˜-10B and Table 2. In Table 2, the semiconductor composite layer structure of merely one wetting layer on the dielectric layer, the semiconductor composite layer structure of a wetting layer and a stiff layer on the dielectric layer, and the semiconductor composite layer structure of a first wetting layer, a stiff layer and second wetting layer on the dielectric layer with different values of sum of length R22 and distance R23 (R22+R23) are compared in Table 2. As shown in Table 2, despite the value of sum of length R22 and distance R23 (R22+R23) is equal to 45 μm, 50 μm or 60 μm, the first wetting layer, the stiff layer and the second wetting layer disposed on the dielectric layer has a smaller quantity of pad cracking than the quantity of pad cracking occurring in merely one wetting layer or a wetting layer and a stiff layer on the dielectric layer.

FIGS. 11A and 11B illustrate a top view diagram and a cross section diagram of a semiconductor packaging structure according to still another embodiment of the invention. In order to simplify the description, merely the first conductive layer 320, the semiconductor composite layer structure 340 and the second conductive layer 360 are illustrated.

Please refer to FIGS. 11A and 11B, the semiconductor composite layer structure 340 is disposed on the first region A3 and second region B3 of the substrate (not illustrated), the wire bonding ball (not illustrated) is disposed in the opening of the passivation layer (not illustrated) and corresponding to the second region B3 of the substrate. The first region A3 surrounds the second region B3. The first region A3 has a length R31, the second region B3 has a length R32. A gap region C3 is between the first region A3 and the second region B3, and has a distance R33.

The difference between the semiconductor packaging structure 30 in FIG. 11A and the semiconductor packaging structure 25 in FIG. 10A is that the semiconductor composite layer structure 340 of the semiconductor packaging structure 30 at the first region A3 configures in a larger density than that at the second region B3, and a distance R33 is between the semiconductor composite layer structure 340 at the first region A3 and the semiconductor composite layer structure 340 at the second region B3. The distance R33 is smaller than the distance R34 between each semiconductor composite layer structure 340 at the second region B3. In this embodiment, the length R32 and the composition of the semiconductor composite layer structure may affect the result of pad cracking, and the experiment result is shown in Table 3.

TABLE 3

| | R32 length | Number of |
|---|---|---|
| | (μm) | pad cracks |
| merely one wetting layer on | 45 | 9 |
| the dielectric layer | 50 | 2 |
| | 60 | 4 |
| a wetting layer and a stiff | 45 | 4 |
| layer on the dielectric layer | 50 | 1 |
| | 60 | 3 |
| a first wetting layer, a stiff | 45 | 0 |
| layer and second wetting | 50 | 1 |
| layer on the dielectric layer | 60 | 0 |

Please refer to FIGS. 11A˜11B and Table 3. In Table 3, the semiconductor composite layer structure of merely one wetting layer on the dielectric layer, the semiconductor composite layer structure of a wetting layer and a stiff layer on the dielectric layer, and the semiconductor composite layer structure of a first wetting layer, a stiff layer and second wetting layer on the dielectric layer with different length R32 are compared in Table 3. As shown in Table 3, despite the length R22 is 45 μm, 50 μm or 60 μm, the first wetting layer, the stiff layer and the second wetting layer disposed on the dielectric layer has a smaller quantity of pad cracking than the quantity of pad cracking occurring in merely one wetting layer or a wetting layer and a stiff layer on the dielectric layer.

Based on the above, the semiconductor composite layer structure and the semiconductor packaging structure having the same in the embodiments of this invention utilize a stiff layer for providing a support and resist a stress caused by bond wiring process. Besides, the semiconductor composite layer structures in the embodiments of this invention have a second wetting layer to improve the adhesive strength with the second conductive layer and avoid the occurrence of void. Moreover, the semiconductor composite layer structures in the embodiments of this invention have a first wetting layer and a stiff layer to improve the problems of stress mismatching between the conductor layer and the dielectric layer, and solve the problems of de-lamination during pad bonding process.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor composite layer structure, disposed on a substrate having an electronic circuit structure and a first conductive layer, the semiconductor composite layer structure comprising:
a plurality of dielectric layers, disposed on the substrate separately;
a first wetting layer, disposed on the dielectric layers and on the substrate between the dielectric layers;
a stiff layer, disposed on the first wetting layer; and
a second wetting layer, disposed on the stiff layer, for contacting with a second conductive layer.

2. The semiconductor composite layer structure according to claim 1, wherein each of the dielectric layers is polygon, rectangle, trapezoid or T shaped.

3. The semiconductor composite layer structure according to claim 1, wherein each of the dielectric layers comprises a top surface and at least one side surface, the first wetting layer covers the top surfaces and the at least one side surfaces of the dielectric layers and the substrate between the dielectric layers, an edge region is at a connecting part between each of the top surfaces and each of the at least one side surfaces, and a thickness of the stiff layer on the first wetting layer and corresponding to the edge region is larger than a thickness of the stiff layer on the first wetting layer and corresponding to the at least one side surface.

4. The semiconductor composite layer structure according to claim 3, wherein a thickness of the stiff layer on the first wetting layer and corresponding to two adjacent dielectric layers of the dielectric layers, is smaller than the thickness of the stiff layer on the first wetting layer and corresponding to the edge region, and the thickness of the stiff layer on the first wetting layer and corresponding to the two adjacent dielectric layers is larger than the thickness of the stiff layer on the first wetting layer and corresponding to the side surface.

5. The semiconductor composite layer structure according to claim 1, wherein the stiff layer is formed by a reactive DC sputtering process.

6. The semiconductor composite layer structure according to claim 1, wherein the first wetting layer and the second wetting layer are metal or alloy, and the stiff layer is metal or inter-metallic compound.

7. The semiconductor composite layer structure according to claim 6, wherein the first wetting layer and the second wetting layer are titanium or titanium tungsten, and the stiff layer is tantalum or titanium nitride.

8. A semiconductor packaging structure, comprising:
a substrate, comprising an electronic circuit structure and a first conductive layer disposed on the electronic circuit structure;
a semiconductor composite layer structure, disposed on the first conductive layer and corresponding to a first region of the substrate, comprising:
a plurality of dielectric layers, disposed on the substrate separately;
a first wetting layer, disposed on the dielectric layers and the substrate between the dielectric layers;
a stiff layer, disposed on the first wetting layer; and
a second wetting layer, disposed on the stiff layer;
a second conductive layer, disposed on the second wetting layer;
a passivation layer, disposed on the second conductive layer, and the passivation layer having an opening; and
a wire bonding ball, disposed in the opening and corresponding to a second region of the substrate, wherein a distance is between the first region and the second region.

9. The semiconductor packaging structure according to claim 8, wherein each of the dielectric layers is polygon, rectangle, trapezoid or T shaped, and wherein each of the dielectric layers comprises a top surface and at least one side surface, the first wetting layer covers the top surfaces and the at least one side surfaces of the dielectric layers and the substrate between the dielectric layers, an edge region is at a connecting part between each of the top surfaces and each of the at least one side surfaces, and a thickness of the stiff layer on the first wetting layer and corresponding to the edge region is larger than a thickness of the stiff layer on the first wetting layer and corresponding to the at least one side surface.

10. The semiconductor packaging structure according to claim 9, wherein a thickness of the stiff layer on the first wetting layer and corresponding to two adjacent dielectric layers of the dielectric layers, is smaller than the thickness of the stiff layer on the first wetting layer and corresponding to the edge region, and the thickness of the stiff layer on the first wetting layer and corresponding to the two adjacent dielectric layers is larger than the thickness of the stiff layer on the first wetting layer and corresponding to the side surface.

11. The semiconductor packaging structure according to claim 8, wherein a length of the first region is larger than or equal to 10 μm, a length of the second region is larger than or equal to 60 μm, and distance between the first region and the second region is larger than or equal to 10 μm.

12. The semiconductor packaging structure according to claim 11, wherein a thickness of the second conductive layer upon the semiconductor composite layer structure is larger than or equal to 1 μm.

13. The semiconductor packaging structure according to claim 8, wherein the first wetting layer and the second wetting layer are metal or alloy, and the stiff layer is metal or inter-metallic compound.

14. The semiconductor packaging structure according to claim 13, wherein the first wetting layer and the second wetting layer are titanium or titanium tungsten, and the stiff layer is tantalum or titanium nitride.

15. The semiconductor packaging structure according to claim 8, wherein the first conductive layer comprises silicon oxide, and the second conductive layer comprises aluminum, and the wire bonding ball comprises copper.

16. The semiconductor packaging structure according to claim 8, wherein the first region surrounds the second region.

17. The semiconductor packaging structure according to claim 8, wherein the semiconductor composite layer structure is further disposed on the first conductive layer and corresponds to the second region of the substrate.

18. The semiconductor packaging structure according to claim 17, wherein the semiconductor composite layer structure corresponding to the first region has a first density, and the semiconductor composite layer structure corresponding to the second region has a second density, and the first density is larger than or equal to the second density.

19. The semiconductor packaging structure according to claim 8, wherein the wire bonding ball comprises a wire, and the wire has a diameter smaller than or equal to 30 μm.

20. The semiconductor packaging structure according to claim 8, wherein the stiff layer is formed by a reactive DC sputtering process.
